(19) United States
(12) Patent Application Publication
(10) Pub. No.: US 2026/0333739 A1
(43) Pub. Date: Oct. 22, 2026

(54) SEMICONDUCTOR DEVICE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Shih-Yen LIN, New Taipei City (TW); Che-Jia CHANG, Taichung City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 19/255,445

(22) Filed: Jun. 30, 2025

Related U.S. Application Data
(60) Provisional application No. 63/792,050, filed on Apr. 21, 2025.

(51) Int. Cl. H10D 30/47; H10D 30/01

(52) U.S. Cl. CPC H10D 30/481; H10D 30/017

(57) ABSTRACT

A semiconductor device includes a substrate, a transition metal dichalcogenide (TMD) layer, a plurality of source/drain metals, and a gate metal. The TMD layer disposed over the substrate. The TMD layer includes a channel region and a plurality of source/drain regions on opposite sides of the channel region. The source/drain metals are disposed over the substrate and electrically coupled to the source/drain regions of the TMD layer, respectively. The gate metal is disposed over the substrate and laterally spaced from the channel region of the TMD layer. The gate metal is positioned such that the gate metal does not overlap the TMD layer in a vertical direction.

### PRIORITY CLAIM AND CROSS-REFERENCE

This application claims priority to U.S. Provisional Application Ser. No. 63/792,050, filed Apr. 21, 2025, which is herein incorporated by reference in its entirety.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-8C and 10A-10C illustrate schematic views of intermediate stages in the formation of a semiconductor structure in accordance with some embodiments of the present disclosure.

FIGS. 8D and 8E illustrate schematic top views of semiconductor structures corresponding to a region in FIG. 8A in accordance with some embodiments of the present disclosure.

FIGS. 9A-9C illustrates schematic views of a semiconductor device in accordance with some embodiments of the present disclosure.

FIGS. 11A-11C and 11E illustrate relationships between gate voltage changes and grain current of semiconductor structures in accordance with some embodiments of the present disclosure.

FIG. 11D illustrates relationship between Raman shift and Raman intensity of semiconductor structures in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In some embodiments, although 2D materials can be used for electronics, interfaces like those with dielectric layers can degrade performance. Using a monolayer transition metal dichalcogenide (TMD) layer as a shield may offer some improvement but isn't enough to fully prevent these effects. Therefore, the present disclosure introduces a TMD (e.g., MoS₂) in-plane gate transistor (IPGT). In some embodiments, the fabrication of TMD IPGT device can include transferring CVD-grown TMD onto a substrate using polydimethylsiloxane (PDMS) stamping to ensure consistent film attachment. Photolithography and metal lift-off can be used to form metal electrodes. The TMD IPGT device can have improved current modulation via in-plane gates.

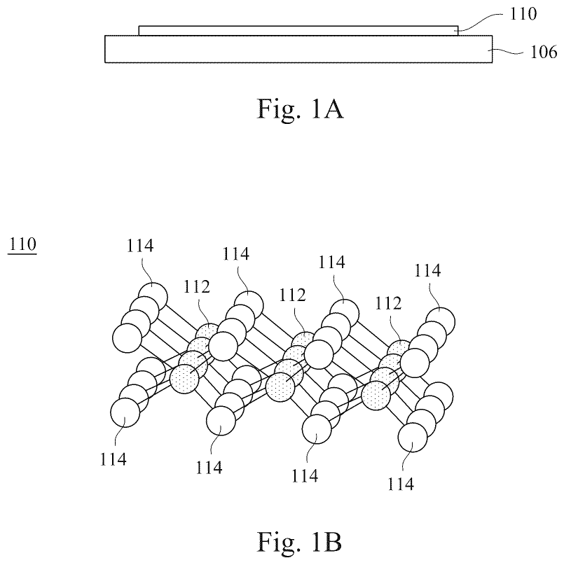

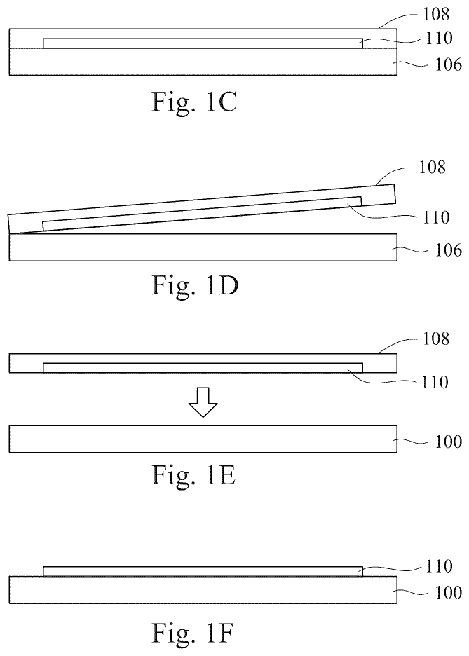

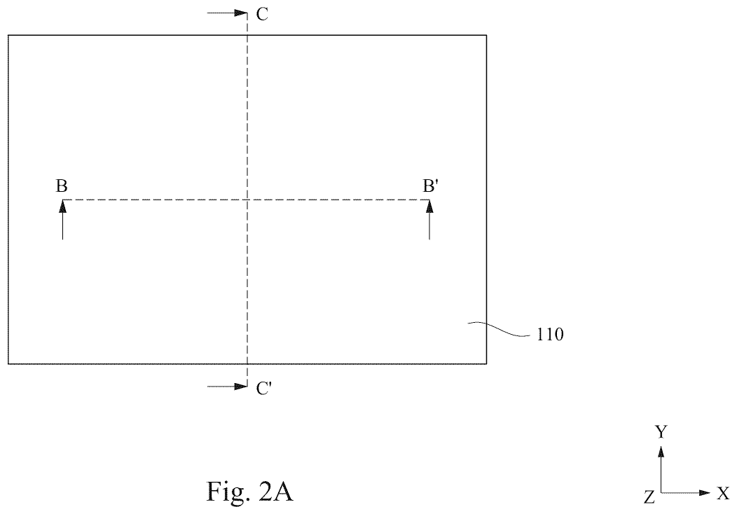

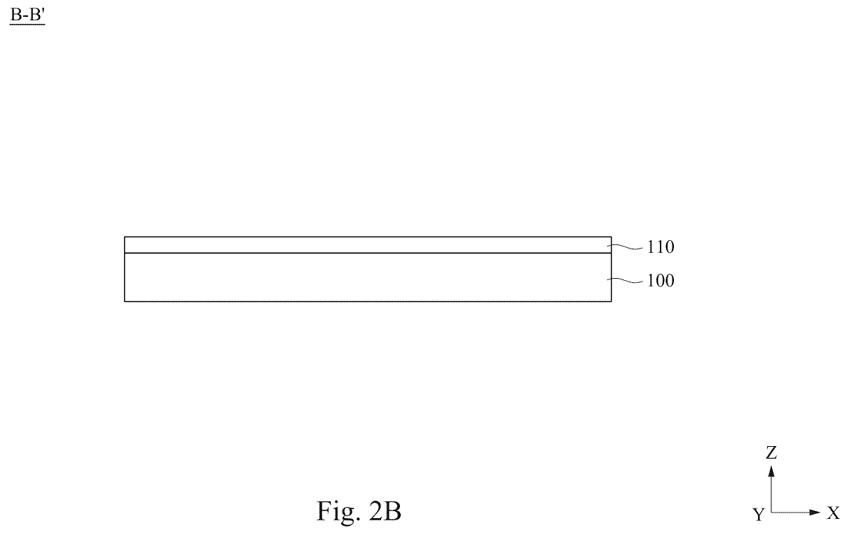

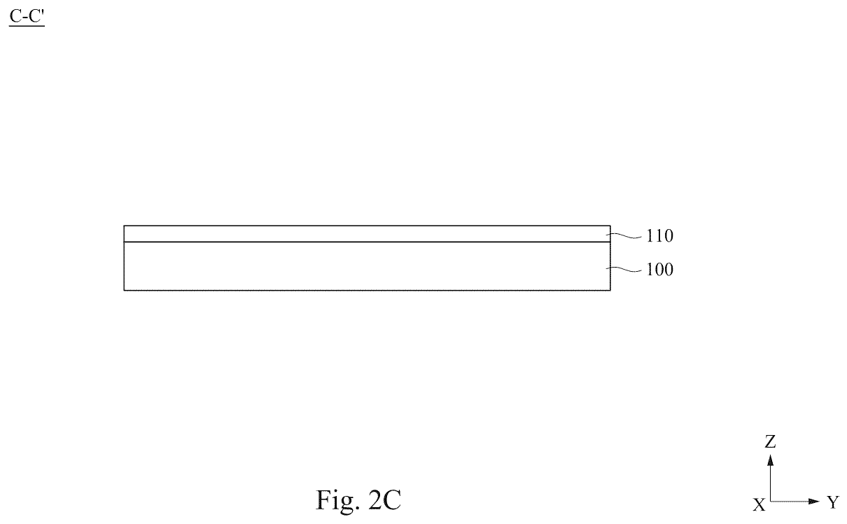

Reference is made to FIGS. 1A-8C and 10A-10C. FIGS. 1A-8C and 10A-10C illustrate schematic views of intermediate stages in the formation of a semiconductor structure in accordance with some embodiments of the present disclosure. FIGS. 1A and 1C-1F show various stages of a sequential process for manufacturing a single crystalline transition metal dichalcogenide (TMD) layer in accordance with some embodiments of the present disclosure. FIG. 1B illustrates a schematic view of a mono-layer of an example TMD in accordance with some embodiments of the present disclosure. FIGS. 2A to 8C illustrate schematic views of intermediate stages in the formation of a semiconductor device 10 in accordance with some embodiments of the present disclosure. It is understood that additional operations can be provided before, during, and after the processes shown by FIGS. 1A-8C and 10A-10C, and some of the operations described below can be replaced or eliminated, for additional embodiments of the method. The order of the operations/processes may be interchangeable.

Reference is made to FIGS. 1A and 1B. A single crystalline transition metal dichalcogenide (TMD) layer 110 can be first fabricated over a dummy (initial) substrate 106, which serves as a temporary base for growth. This TMD layer 110 can be subsequently transferred onto a device substrate, where it is utilized for the fabrication of field-effect transistors (FETs). As shown in FIG. 1A, the single crystalline TMD layer 110 can be grown on the substrate 106. The choice of substrate can control the nucleation and growth characteristics of the TMD material.

In some embodiments, the substrate 106 can include sapphire, silicon oxide (SiO₂), hafnium oxide, Si, other suitable material, or combinations thereof. In some embodiments, the substrate 106 can be selected from a range of materials depending on the desired TMD growth conditions. In some embodiments, substrates like γ-Al₂O₃ (110), Ga₂O₃ (110), or MgO (110) can be selected due to their crystalline structures, which match well with the hexagonal symmetry of the TMDs, facilitating high-quality, single-crystal TMD growth. These materials can promote epitaxial growth of the TMD layer 110, resulting in a single crystalline film with minimal grain boundaries, ensuring high mobility and low defect density in the final device.

Alternatively, in other embodiments, a (110) silicon (Si) substrate can be used. Silicon substrates can be employed in semiconductor manufacturing due to their well-established processing techniques and compatibility with standard device fabrication methods. The (110) orientation of can align the crystal structure of the TMD layer 110, ensuring proper lattice matching and facilitating the growth of large-area, high-quality TMD films. The formation of the TMD layer 110 on the substrate 110 can allow for precise control over the crystallinity, thickness, and uniformity of the TMD material, which in turn allows for achieving high-performance FETs. After the TMD layer 110 is grown and characterized, it is transferred to a device substrate using techniques such as PDMS transfer or wet etching, which in turn minimizes defects and maintains the integrity of the single-crystal TMD layer 110 during integration into the FET device.

As shown in FIG. 1B, the single-crystal TMD layer 110 can consist of two components: transition metal atoms 112 and chalcogen atoms 114, which are organized in a specific atomic structure defining the material's properties. The transition metal atoms 112 can form a central layer located in the middle of the TMD monolayer, serving as the core element of the crystalline structure. The transition metals can include tungsten (W) or molybdenum (Mo), which can have robust electronic and optical properties. The chalcogen atoms 114 can be arranged in a layered configuration relative to the transition metal atoms, with a first layer of chalcogen atoms positioned above the transition metal atoms and a second layer of chalcogen atoms located below the transition metal atoms. The chalcogen atoms 114 can include sulfur (S), selenium (Se), or tellurium (Te), which can determine the electronic band structure and optoelectronic characteristics of the TMD material. The combination of one layer of transition metal atoms and two layers of chalcogen atoms, arranged in a single atomic plane, can be referred to as a monolayer of the single-crystal TMD layer 110, which can be one molecule thick and highly ordered, contributing to the material's unique physical properties such as high mobility, strong light-matter interaction, and mechanical flexibility.

The fabrication of the single-crystal TMD layer 110 can include several steps. First, substrate preparation, where a suitable substrate such as sapphire, SiO₂, or Si can be chosen based on the crystallization conditions. Then, chemical vapor deposition (CVD), where a precursor material containing the transition metal (such as MoO₃ or WO₃) and a chalcogen source (such as sulfur or selenium) is heated in a reaction chamber, promoting the reaction between the metal and chalcogen atoms to form the TMD monolayer. Next, controlled growth conditions, where the temperature, pressure, and gas flow rates can be regulated to promote the lateral growth of the TMD layer 110 and ensure it remains single-crystalline. In addition, nucleation control, where a nucleation pattern may be employed to guide the growth of the TMD layer 110, ensuring uniformity and minimizing defects. Post-growth characterization follows, using techniques such as Raman spectroscopy, atomic force microscopy (AFM), and scanning electron microscopy (SEM) to confirm the quality, thickness, and crystalline structure of the TMD layer. In some embodiments, the TMD layer 110 can be interchangeable referred to as a two-dimensional (2-D) material layer.

Reference is made to FIGS. 1C and 1D. A stamp layer 108 can be formed over the TMD layer 110 and the substrate 106, instead of PDMS. In some embodiments, the stamp layer 108 can be made of polydimethylsiloxane (PDMS). A layer of PDMS is pressed onto the TMD layer 110 and then the stamp layer 108 can be peeled as shown in FIG. 1D. Due to strong adhesion between the TMD layer 110 and the stamp layer 108, the TMD layer 110 can be also peeled off from the substrate 106 together with the stamp layer 108. In some embodiments, the structure of FIG. 1C can be immersed in deionized water and the substrate 106 can be detached. Ultrasonic vibrations may be applied to the substrate 106.

Reference is made to FIGS. 1E and 1F. The detached TMD layer 110 supported by the stamp layer 108 can be transferred to a substrate 100. Further, the stamp layer 108 can be removed as shown in FIG. 1F. In some embodiments, wet etching can be used to remove the stamp layer 108. For example, when the stamp layer 108 is made of an organic material, such as PMMA and PDMS, an organic solvent, such as acetone, can dissolve the organic material, thereby removing the stamp layer 108. When a Cu layer used, the Cu layer is removed by using FeNO₃ solution.

Reference is made to FIGS. 2A-8C and 10A-10C, in which FIGS. 2A, 3A, 4A, 5A, 6A, 7A, 8A, and 10A, are top views of a semiconductor device 10, FIGS. 2B, 3B, 4B, 5B, 6B, 7B, 8B, and 10B are cross-sectional views along line B-B′ of FIGS. 2A, 3A, 4A, 5A, 6A, 7A, 8A, and 10A, and FIGS. 2C, 3C, 4C, 5C, 6C, 7C, 8C, and 10C are cross-sectional views along line C-C′ of FIGS. 2A, 3A, 4A, 5A, 6A, 7A, 8A, and 10A. In some embodiments, the semiconductor device 10 can be an in-plane gate transistor (IPGT), in which the gate electrode can be located laterally (in the same plane) as the source, drain, and channel, rather than in a stacked, vertical configuration. The embodiment depicted in FIGS. 2A-8C and 10A-10C may reuse reference numerals and/or letters across different examples. This repetition is intended for clarity and simplicity and does not imply any direct relationship between the various embodiments or configurations presented.

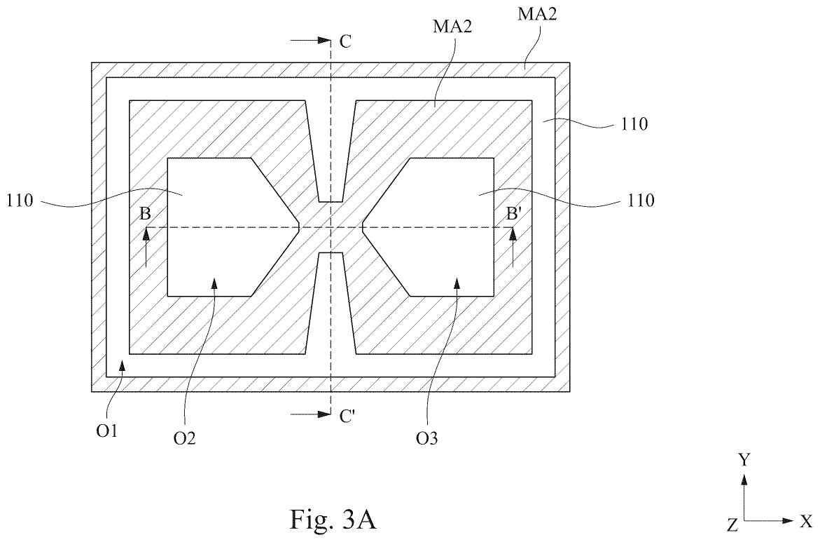

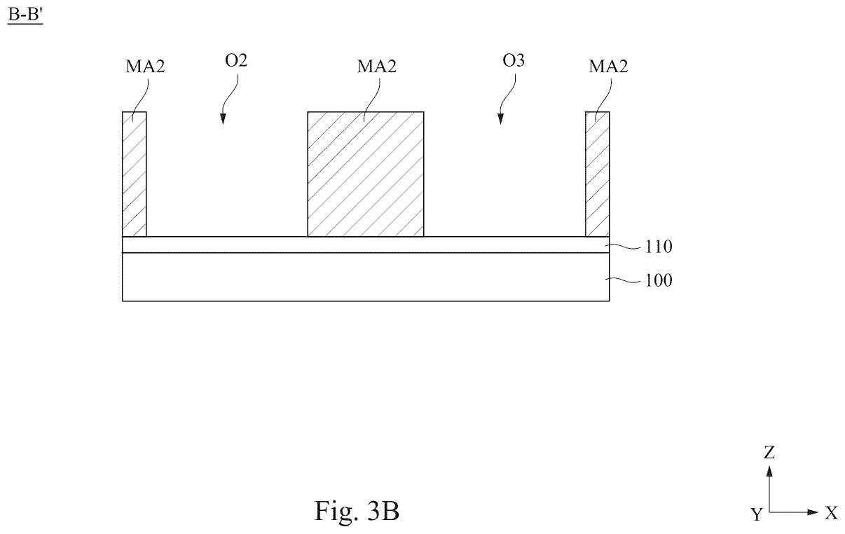

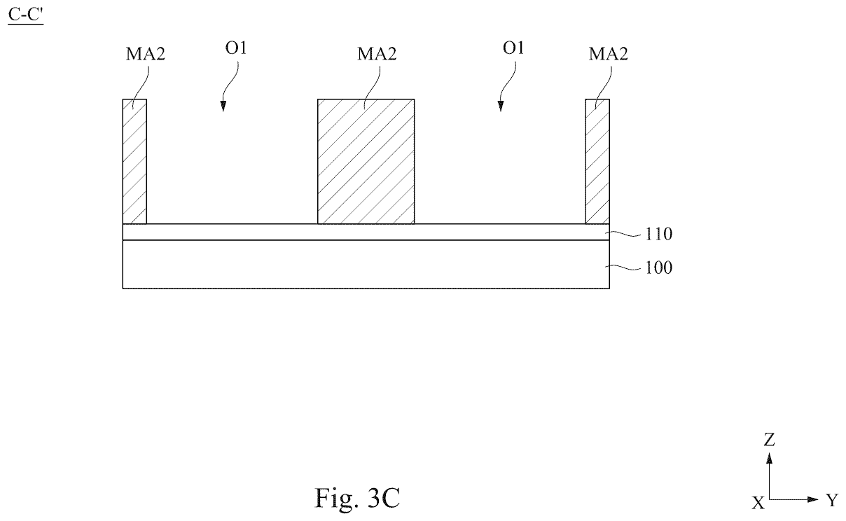

As shown in FIGS. 2A-2C, once the TMD layer 110 is transferred to the second substrate 100 and, if necessary, subjected to an optional trimming process, a field-effect transistor (FET) can be fabricated using the single-crystal TMD layer 110. The process for this is described in detail in FIGS. 3A-8C and 10A-10C. In some embodiments, the TMD layer 110 shown in FIGS. 2A-2C may be a mono-layer transition metal dichalcogenide formed on the substrate 100 through a single transferring process as illustrated in FIGS. 1A-1F. In some embodiments, the TMD layer 110 may be a bi-layer transition metal dichalcogenide formed on the substrate 100 through two successive transferring processes as depicted in FIGS. 1A-1F. In other embodiments, the TMD layer 110 may be a multi-layer transition metal dichalcogenide, comprising more than two layers (e.g., 3, 4, 5, 6, 7, 8, 9, or 10 layers), formed on the substrate 100 through multiple sequential transferring processes similar to those shown in FIGS. 1A-1F.

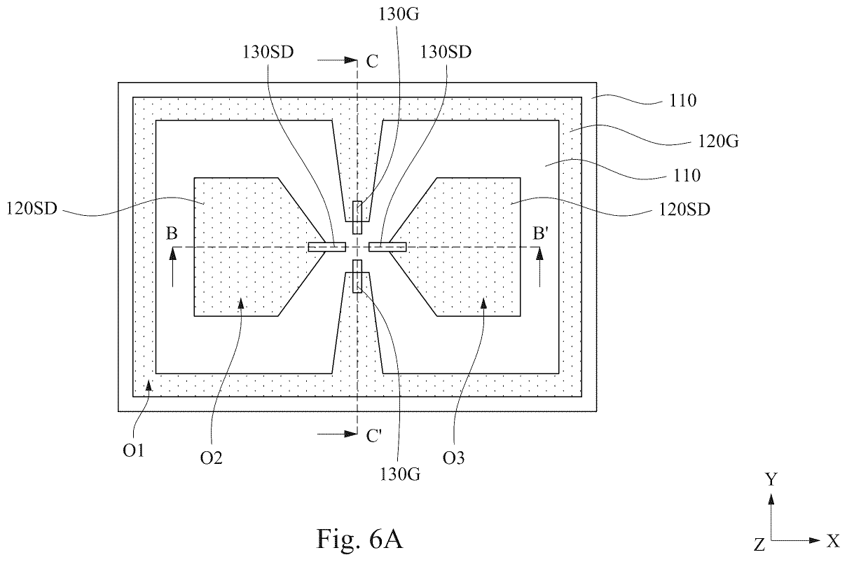

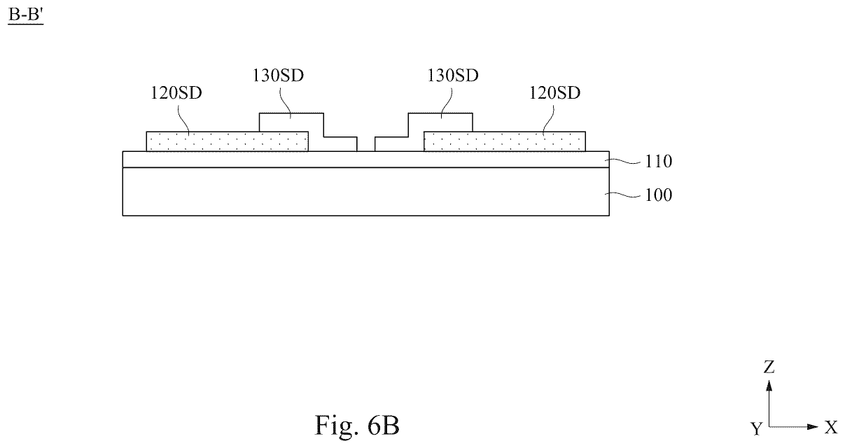

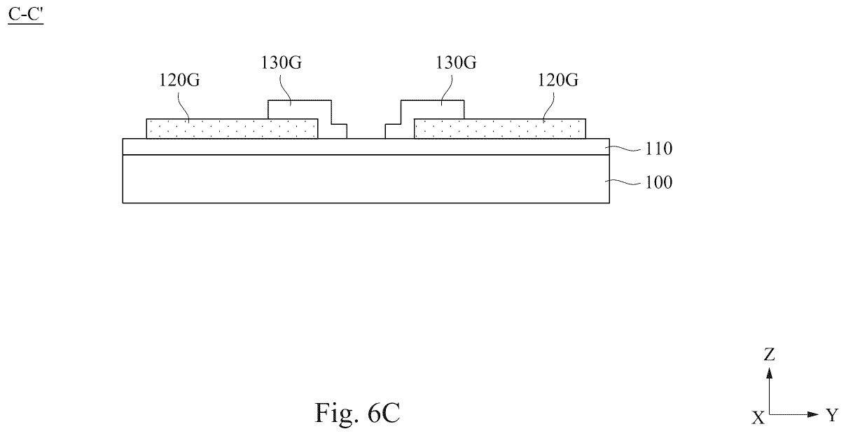

Reference is made to FIGS. 3A-3C. A patterned mask layer MA2 can be formed on the substrate 100, extending over and covering the underlying TMD layer 110. The patterned mask MA2 can include strategically positioned openings O1, O2, and O3, designed to selectively expose specific regions of the upper surface of the TMD layer 110. In some embodiments, these openings O1, O2, and O3 can define the positions, shapes, and dimensions of subsequent electrode structures, including a gate contact electrode 120G (as depicted in FIGS. 6A to 8C) and source/drain contact electrodes 120SD (as also illustrated in FIGS. 6A to 8C). More specifically, the opening O1 may be configured to entirely enclose the openings O2 and O3, thereby providing structural alignment and positional referencing among the electrodes. Additionally, opening O1 may be designed to include a rectangular, ring-shaped portion that surrounds the openings O2 and O3, as well as two elongated extension portions that directly connect to the inner sidewall of this rectangular ring-shaped portion. These tailored geometric features of the opening O1 can serve to clearly delineate and isolate the gate contact region from the source/drain contact regions, thereby facilitating precise alignment during subsequent metallization or contact formation steps.

In terms of material composition, the patterned mask MA2 may be implemented as a photoresist layer in some embodiments. Such a photoresist layer can be deposited onto the substrate 100 by various techniques, including spin coating, spray coating, or other suitable coating methods. This photoresist layer typically can include a photosensitive material whose chemical or physical properties, such as solubility in specific developing solutions, can be altered upon exposure to ultraviolet (UV) or other suitable types of radiation. Consequently, selective exposure of the photoresist through a photomask, followed by appropriate development, can enable the formation of precisely defined openings O1, O2, and O3, for subsequent fabrication steps. This controlled lithographic patterning can ensure accurate alignment, reproducibility, and structural integrity for the resulting device components.

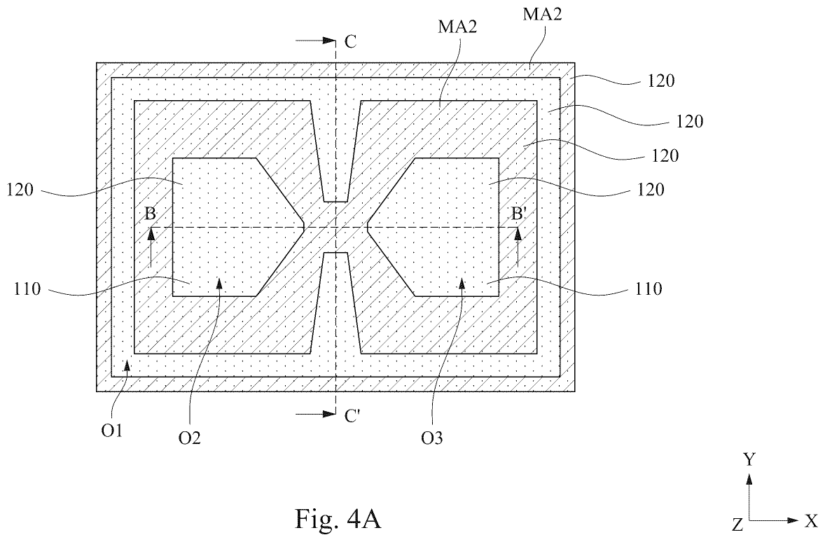

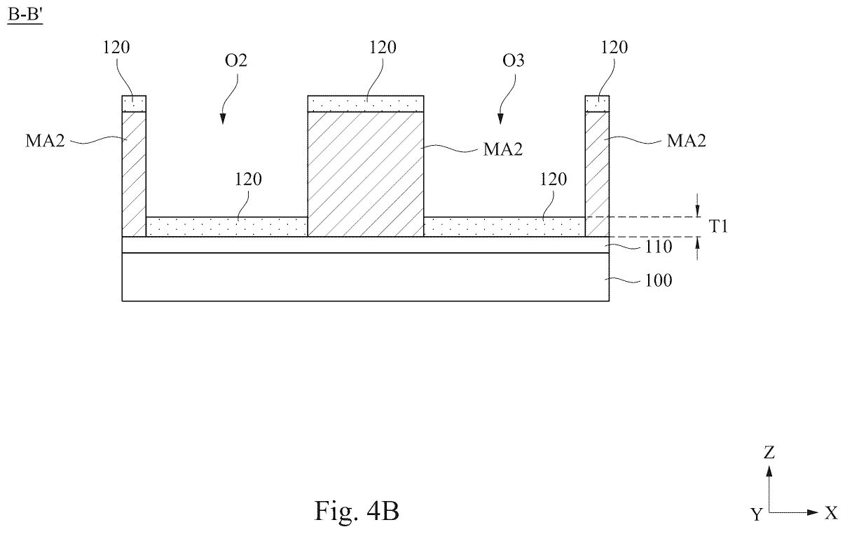

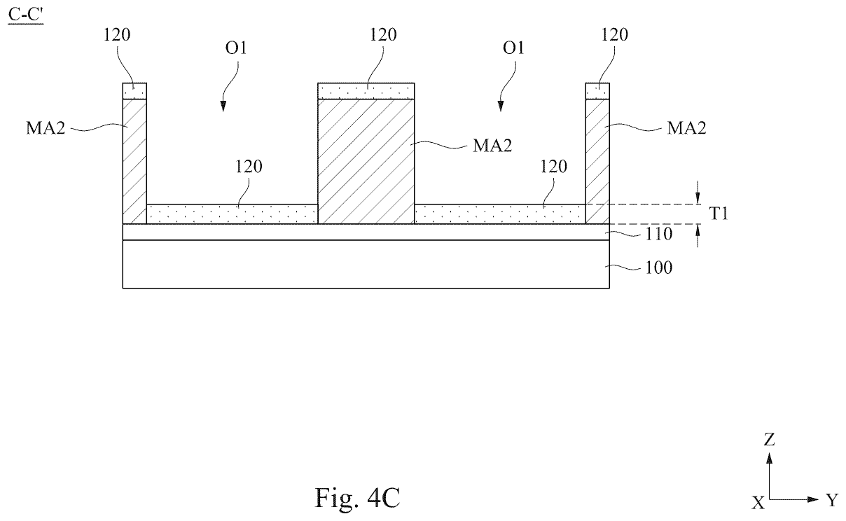

Reference is made to FIGS. 4A-4C. A contact electrode layer 120 can be subsequently deposited over the patterned mask MA2, effectively filling the openings O1, O2, and O3 defined by the patterned mask MA2. As a result, portions of the contact electrode layer 120 deposited within the openings O1, O2, and O3 directly contact the exposed upper surface regions of the underlying TMD layer 110. In some embodiments, the deposition of the contact electrode layer 120 may be carried out using physical deposition techniques, such as physical vapor deposition (PVD), electron-beam (e-gun) evaporation deposition, sputtering, or other applicable methods known in semiconductor fabrication. These deposition methods can exhibit anisotropic characteristics, meaning they may provide a higher deposition rate on horizontally oriented surfaces compared to vertically oriented surfaces. Consequently, the contact electrode layer 120 can form a thicker and more uniform deposition on horizontal regions, such as the upper surfaces of the patterned mask MA2 and the exposed horizontal regions of the TMD layer 110, while forming comparatively thinner depositions on the vertical sidewalls of the patterned mask MA2 and other vertically oriented features.

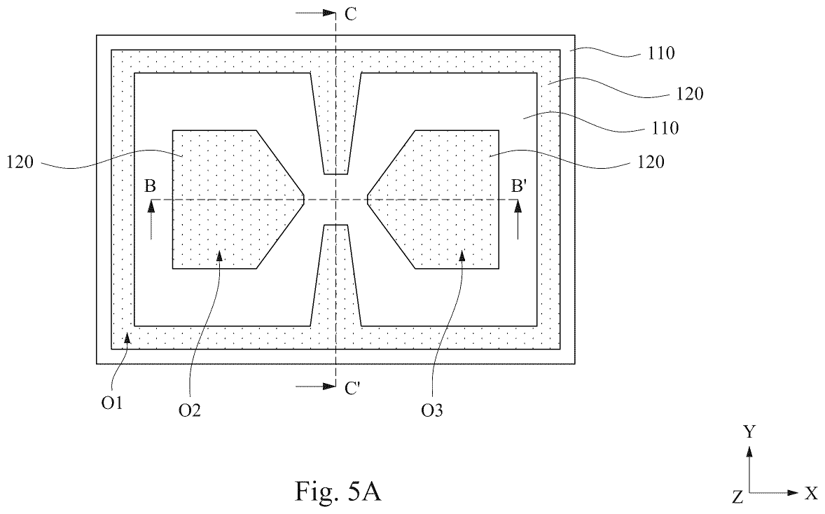

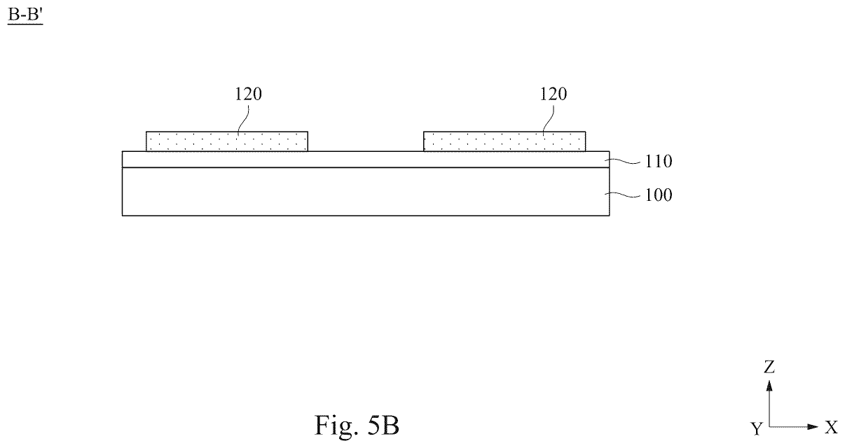

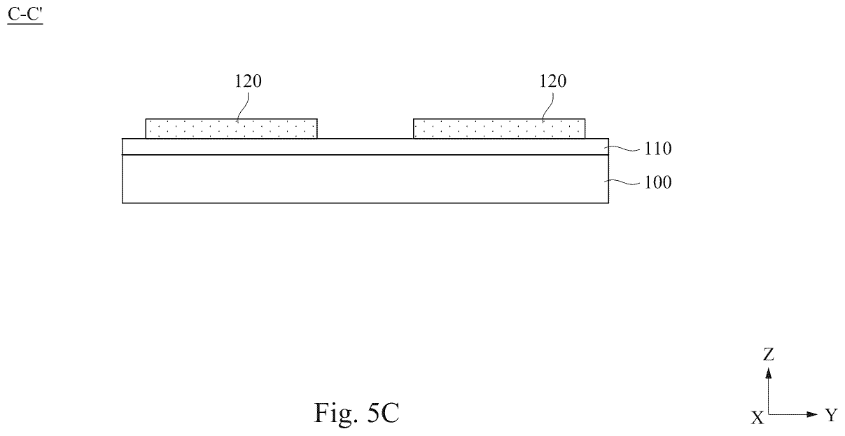

The contact electrode layer 120 can be formed through a deposition process conducted at a temperature ranging from approximately 25 °C to 100 °C, with specific examples including 25 °C, 30 °C, 40 °C, 50 °C, 60 °C, 70 °C, 75 °C, 80 °C, 90 °C, or 100 °C, which in turn allows for optimizing the interface properties between the contact electrode layer 120 and the underlying TMD layer 110. Operating within this temperature window can effectively reduce contact resistance at the electrode/TMD interface by promoting better adhesion and improving the crystallinity of the deposited metal, thereby enhancing electrical conductivity and overall device performance. Additionally, maintaining the deposition temperature below 100 °C can ensure compatibility with the patterned mask layer MA2 used during the metal lift-off process, as illustrated in FIGS. 5A-5C. This prevents thermal degradation or deformation of the patterned mask layer MA, which is composed of temperature-sensitive photoresist materials, thereby preserving pattern fidelity and ensuring clean, well-defined electrode structures. The resulting contact electrode layer 120 can be deposited to a thickness T1, which may range from about 20 nm to 300 nm, depending on the device requirements. For example, the thickness T1 can be tailored to values such as 20 nm, 50 nm, 100 nm, 150 nm, 200 nm, 250 nm, or 300 nm, balancing factors like sheet resistance, step coverage, and mechanical stability to achieve optimal electrical performance within the transistor architecture.

In some embodiments, the contact electrode layer 120 can be made from various conductive materials such as gold (Au), titanium (Ti), palladium (Pd), platinum (Pt), nickel (Ni), aluminum (Al), copper (Cu), other suitable conductive materials, or combinations thereof. In some embodiments, metal stacks like Ti/Au, Cr/Au, or Pd/Au may be used to improve adhesion and reduce contact resistance. Other alternatives can include graphene, carbon nanotube-based electrodes, or transparent conductive oxides like indium tin oxide (ITO) and aluminum-doped zinc oxide (AZO). In some embodiments, conductive metal nitrides such as titanium nitride (TiN) can also be used for the mechanical robustness and chemical stability of the contact electrode layer 120. The choice of conductive materials can depend on electrical performance and compatibility with the TMD layer 110.

Reference is made to FIGS. 5A-5C. The patterned mask MA2 can be subsequently removed, resulting in portions of the contact electrode layer 120 remaining within the openings O1, O2, and O3, as illustrated in FIGS. 4A to 4C. In embodiments where the patterned mask MA2 is composed of photoresist, a lift-off process can be employed to accomplish its removal. The lift-off process can include immersing the substrate with the patterned mask MA2 and the deposited contact electrode layer 120 into a solvent solution specifically chosen to dissolve the photoresist material without adversely affecting the contact electrode layer 120 or underlying substrate 100. In some embodiments, the solvents used in the lift-off process can include acetone, which can be used for positive photoresists; N-methyl-2-pyrrolidone (NMP), which is used for more robust or thermally cured resists; and in some cases, dimethyl sulfoxide (DMSO), toluene, or PGMEA depending on the specific photoresist and process conditions. The solvent can be selected based on its compatibility with the patterned mask MA2 and underlying device layers, ensuring removal of the patterned mask MA2 without damaging the contact electrode layer 12 and the TMD layer 110.

During immersion, the solvent can penetrate and dissolve the patterned mask MA2, effectively detaching it from the TMD layer 110. To accelerate and ensure thorough removal, mild ultrasonic agitation may be applied, facilitating the breakdown and detachment of the photoresist material. As the patterned mask MA2 dissolves, any portions of the contact electrode layer 120 deposited on top of the patterned mask MA2 can be simultaneously detached and removed, leaving behind only the patterned electrode structures formed on the TMD layer 110. This lift-off process thus provides pattern definition and cleanliness without requiring chemical or mechanical etching steps.

After completion of this lift-off process, the remaining patterned electrode layer 120 can constitutes distinct device elements, including a gate contact electrode 120G and source/drain contact electrodes 120SD, as depicted in FIGS. 6A-8C. Specifically, the gate contact electrode 120G can correspond to the region of the contact electrode layer 120 deposited within the opening O1 defined by the patterned mask MA2. Similarly, the source/drain contact electrodes 120SD can correspond to the portions of the contact electrode layer 120 formed within the openings O2 and O3, respectively.

Reference is made to FIGS. 6A-6C. A metal layer 130 can be formed over the substrate 100, covering selected portions of both the TMD layer 110 (such as MoS₂) and the contact electrode layer 120. This metal layer 130 can function as part of the external contact metallization structure, providing low-resistance interconnects to the underlying gate and source/drain regions. In some embodiments, the metal layer 130 can include specific sub-regions corresponding to gate metals 130G and source/drain metals 130SD, which can be electrically and physically coupled to the gate contact electrode 120G and source/drain contact electrodes 120SD, respectively.

As illustrated in FIG. 6B, for the source/drain region, the bottommost surface of each source/drain metal 130SD can be aligned with the bottom surface of the corresponding source/drain contact electrode 120SD, ensuring continuous contact and minimal step coverage discontinuities. The source/drain metals 130SD and the underlying contact electrodes 120SD can be both in direct electrical contact with the exposed surface of the TMD layer 110, forming low-resistance ohmic or Schottky contacts depending on the material pairing and interface treatment. Similarly, as shown in FIG. 6C, the bottommost surface of each gate metals 130G can be aligned with the bottom surface of the corresponding gate contact electrodes 120G, ensuring continuous contact and minimal step coverage discontinuities. The gate metals 130G and the underlying gate contact electrodes 120G can be both in direct electrical contact with the exposed surface of the TMD layer 110, forming low-resistance ohmic or Schottky contacts depending on the material pairing and interface treatment.

In some embodiments, the metal layer 130 can be formed using electron-beam lithography process. In this process, a layer of electron-sensitive resist can be first spin-coated onto the substrate 100, covering the existing structures, including the TMD layer 110 and the contact electrode layer 120, as shown in FIGS. 5A-5C. The pattern for the metal layer 130, which includes the gate metals 130G and source/drain metals 130SD, can be then patterned directly onto the resist using a focused electron beam. Following the exposure, the resist is developed to create openings corresponding to the intended metal features of the gate metals 130G and source/drain metals 130SD. A metal deposition process, such as physical vapor deposition (PVD), can be then performed to deposit the metal material into the patterned regions. After deposition, a lift-off process can be used to remove the remaining resist, leaving behind the well-defined metal structures.

The metal layer 130 can include conductive materials selected based on electrical, chemical, and thermal properties. In some embodiments, the metal layer 130 can include gold (Au), titanium (Ti), palladium (Pd), platinum (Pt), nickel (Ni), aluminum (Al), copper (Cu), other suitable conductive materials, or combinations thereof. In some embodiments, metal stacks like Ti/Au, Cr/Au, or Pd/Au may be used to improve adhesion and reduce contact resistance. Other alternatives can include graphene, carbon nanotube-based electrodes, or transparent conductive oxides like indium tin oxide (ITO) and aluminum-doped zinc oxide (AZO). In some embodiments, conductive metal nitrides such as titanium nitride (TiN) can also be used for the mechanical robustness and chemical stability of the contact electrode layer 120. The choice of conductive materials can depend on electrical performance and compatibility with the TMD layer 110. In some embodiments, the metal layer 130 can be made of a same material as the contact electrode layer 120. In some embodiments, the metal layer 130 can be made of a different material than the contact electrode layer 120.

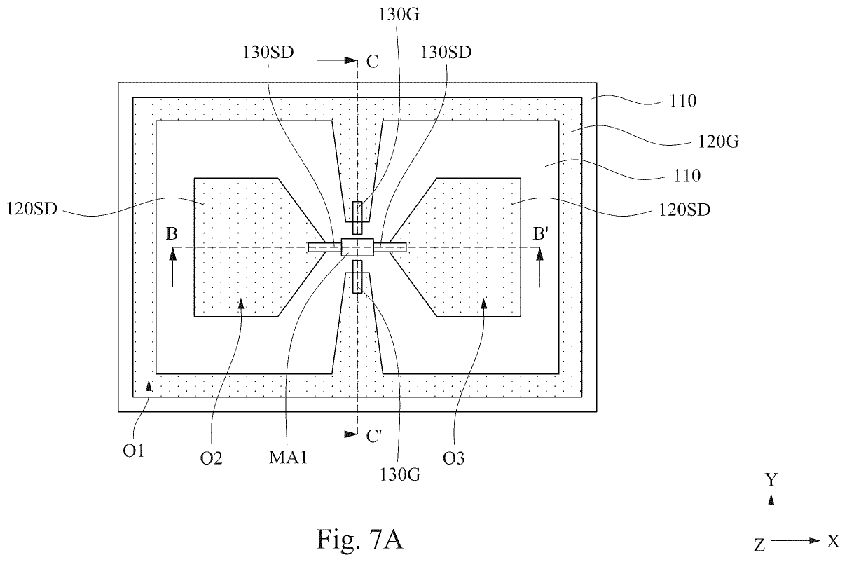

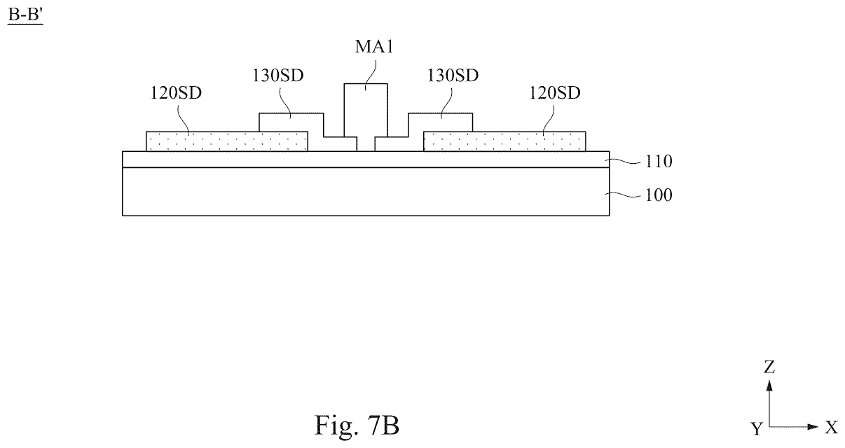

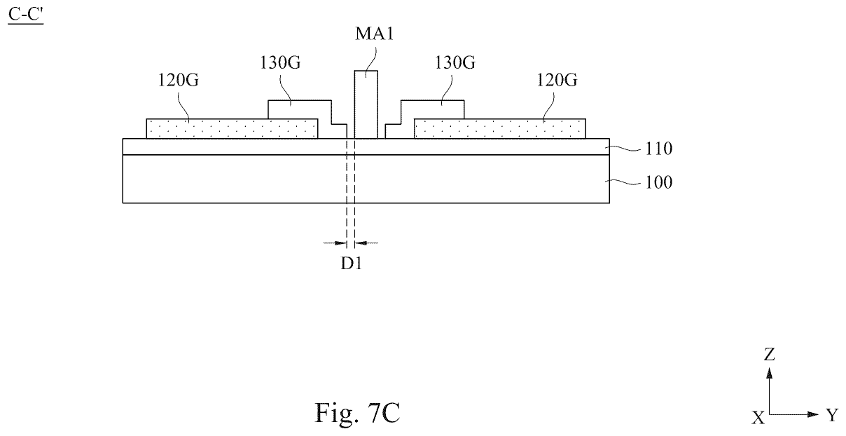

Reference is made to FIGS. 7A-7C. A patterned mask MA1 can be formed over the substrate 100 in a manner that selectively covers regions of both the source/drain metal 130SD and the TMD layer 110. The patterned mask MA1 can define subsequent etching or material removal regions, and in protecting underlying features during anisotropic processing steps. As illustrated in the cross-sectional views of FIGS. 7B and 7C, the patterned mask MA1 can conformally applied such that it comes into direct contact with the top surface of the TMD layer 110, ensuring robust coverage and alignment across varying topographies. In FIG. 7C, the lateral spacing D1, measured along the Y-direction, between the edge of the patterned mask MA1 and each adjacent gate metal 130G is precisely defined within a range of approximately 1 nm to 500 nm, such as approximately 1, 50, 100, 150, 200, 250, 300, 350, 400, 450, or 500 nm, ensuring both electrical isolation and spatial resolution for downstream patterning or etching processes, such as gate dielectric deposition, encapsulation, or isolation trench formation.

The patterned mask MA1 can be formed using a photoresist-based material or a hardmask layer. In some embodiments, the patterned mask MA1 can be a photoresist layer, which can be a positive or negative tone resist depending on whether exposed or unexposed regions are intended to remain. The photoresist can be applied through spin coating, ensuring a uniform thin film over the substrate 100. After spin-coating, a soft bake (prebake) can be performed to evaporate solvents and stabilize the resist film. Subsequently, the photoresist layer can be exposed to patterned ultraviolet (UV) light using photolithography. A photomask containing the specific geometric features can be aligned over the substrate 100, and the UV light alters the solubility of the photoresist in the exposed (positive resist) or unexposed (negative resist) regions. After exposure, the substrate 100 may undergo development using an appropriate developer solution to remove the specific portions of the photoresist layer, resulting in the final patterned structure of MA1. In some embodiments, post-exposure bake (PEB) and hard bake steps may follow to improve resolution, resist adhesion, and thermal stability for subsequent processing. In some embodiments, the patterned mask MA1 can alternatively be implemented as a hard mask, made from materials such as silicon nitride (Si₃N₄) , silicon dioxide (SiO₂), or amorphous carbon. In such cases, a photoresist layer is still used initially to define the pattern, which is then transferred into the hardmask layer using reactive ion etching (RIE). After pattern transfer, the photoresist can be stripped, leaving a high-etch-resistance hard mask that serves as the functional MA1 for further etching.

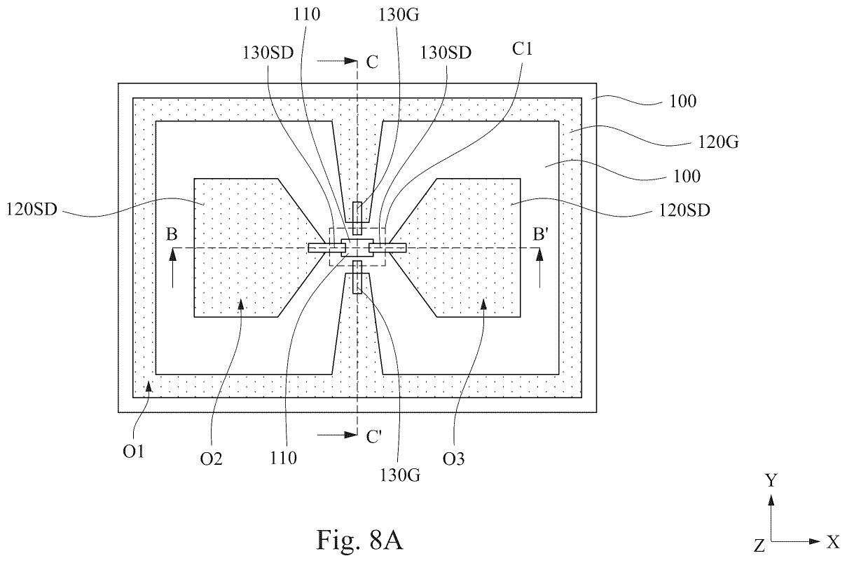

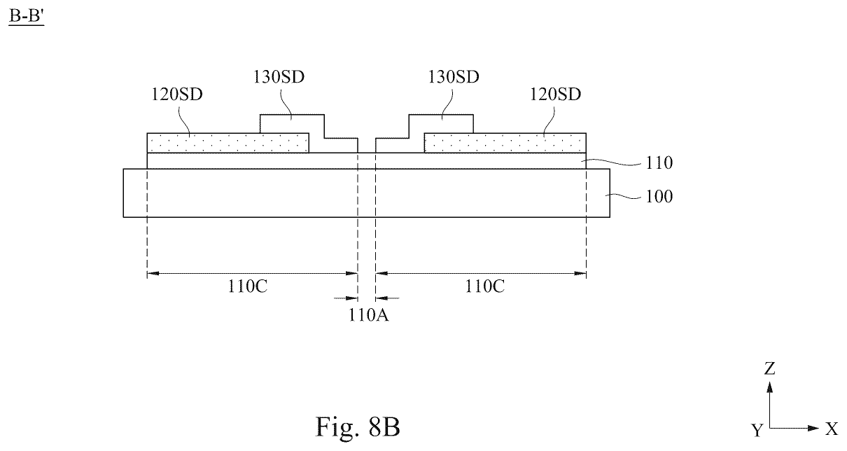

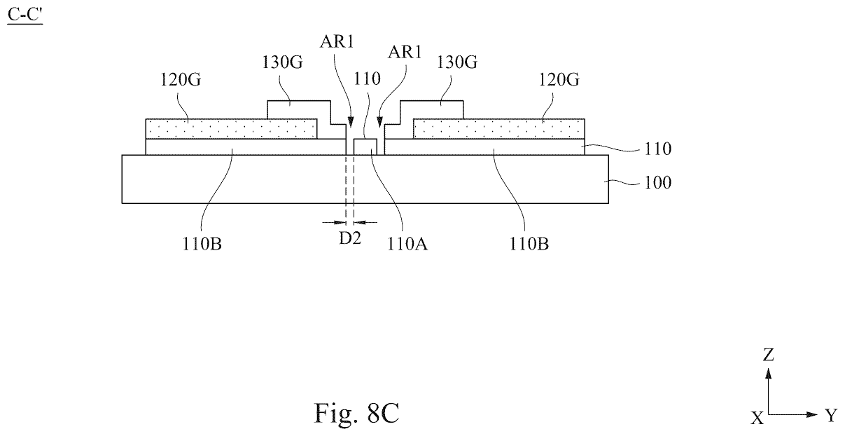

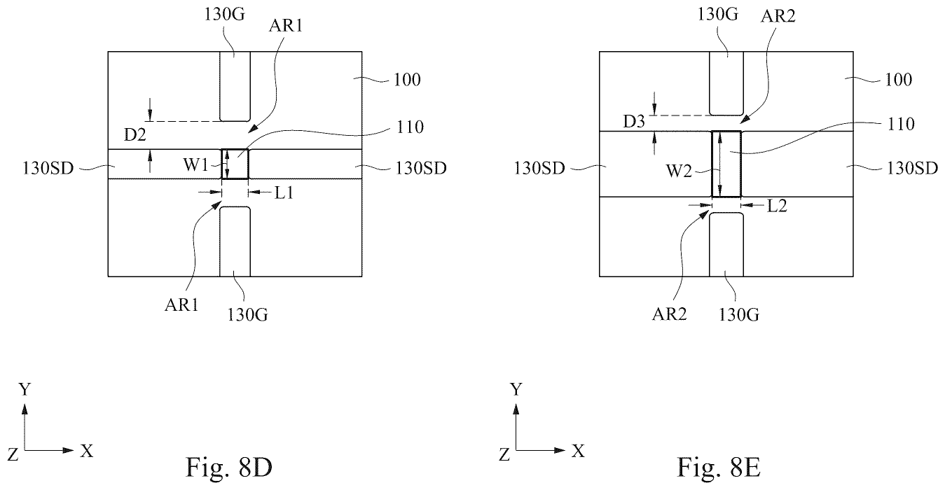

Reference is made to FIGS. 8A-8C. An etching process can be performed to selectively remove portions of the TMD layer 110 that are exposed by the patterned mask MA1, the metal layer 130, and the contact electrode layer 120. This etching step can define the active channel region of the device by spatially isolating specific portions of the TMD layer 110. In some embodiments, the etching process may be carried out using a dry etching method such as reactive ion etching (RIE) with CF₄ plasma, tailored to the specific chemistry and etch selectivity of the TMD layer 110 to avoid damage to adjacent metal layers. Following completion of the etching process, the patterned mask MA1 as shown in FIGS. 7A-7C can be removed, using a solvent-based strip or plasma ashing process, depending on whether the patterned mask MA1 is a photoresist or hard mask. In some embodiments, the etching process can result in the formation of nanoscale air gaps AR1 (see FIG. 8C), which are void regions between the remaining TMD segments and adjacent metal structures. These air gaps AR1 can serve as physical and electrical isolation boundaries. In some embodiments, the air gap AR1 can be interchangeable referred to as a gate-to-channel separation.

Therefore, the etched TMD layer 110 can include two distinct regions: a channel portion 110A and a remaining portion 110B. The channel portion 110A, which serves as the conduction path of the transistor, can be separated from the remaining portion 110B by the air gap AR1. The gate metal 130G over the remaining portion 110B can be laterally spaced from the channel portion 110A, such that the gate metal is positioned such that the gate metal 130G does not overlap the TMD layer 110 in the Z-direction. As shown in FIG. 8C, the remaining portion 110B can be laterally spaced from the channel portion 110A and positioned at a same elevation as the channel portion 110A, and the gate metal 130G over the remaining portion 110B can be positioned at an elevation higher than that of the channel portion 110A. The lateral width D2 (see FIG. 8C) of this air gap AR1, measured along the Y-direction, can be controlled within the range of approximately 1 nm to 500 nm, such as approximately 1, 50, 100, 150, 200, 250, 300, 350, 400, 450, or 500 nm, providing a tunable isolation distance that can influence gate-to-channel coupling and leakage characteristics.

As depicted in the cross-sectional view of FIG. 8B, the channel portion 110A of the TMD layer can be exposed from the source/drain metals 130SD, which form electrical contacts enabling carrier injection into and out of the channel. In FIG. 8B, the etched TMD layer 110 can further includes source/drain regions 110C underlying the source/drain metals 130SD. In FIG. 8C, the remaining portion 110B of the TMD layer 110 can be shown directly underneath and in contact with the gate metals 130G, indicating that the gate electrode is structurally and electrically interfaced with the isolated TMD region. In some embodiments, the top surface of the remaining portion 110B can be in direct contact with the gate metals 130G, forming a device configuration in which the gate electrode is not vertically aligned over the channel, but laterally offset by a nanometer-scale gap.

Reference is made to FIGS. 8D and 8E. FIGS. 8D and 8E illustrate schematic top views of semiconductor structures corresponding to a region C1 in FIG. 8A in accordance with some embodiments of the present disclosure. While FIGS. 8D and 8E illustrate embodiments of the semiconductor devices with a different structural configuration than the semiconductor device 10 in FIGS. 1A-8C, the present disclosure may repeat reference numerals and/or letters in the various examples. This repetition is for simplicity and clarity and does not dictate a relationship between the various embodiments and/or configurations discussed. Specifically, FIGS. 8D and 8E illustrate the spatial and functional relationship between the gate metals 130G, the source/drain metals 130SD, and the channel portion 110A of the TMD layer 110. These figures provide a top-down or plan-view perspective that complements the cross-sectional illustrations and offer insight into the lateral alignment and dimensional configuration of device components. FIGS. 8D and 8E may show how the gate metals 130G can be laterally offset from the TMD channel, forming the air gap AR1 that electrically isolates the gate metals 130G from the channel region while still enabling capacitive coupling for field-effect modulation.

As illustrated in FIG. 8D, the effective channel length L1 can be defined along the X-direction, representing the distance over which charge carriers travel between the source and drain electrodes (i.e., source/drain metals 130SD) within the TMD layer 110. In some embodiments, the effective channel length L1 can range from about 1-500 nm, such as approximately 1, 10, 50, 100, 150, 200, 250, 300, 350, 400, 450, or 500 nm. The channel width W1 can be defined along the Y-direction, representing the lateral extent of the conduction path available for carrier transport. These two dimensions (i.e., effective channel length L1 and channel width W1) are parameters influencing the electrical performance of the in-plane gate transistor (IPGT) device.

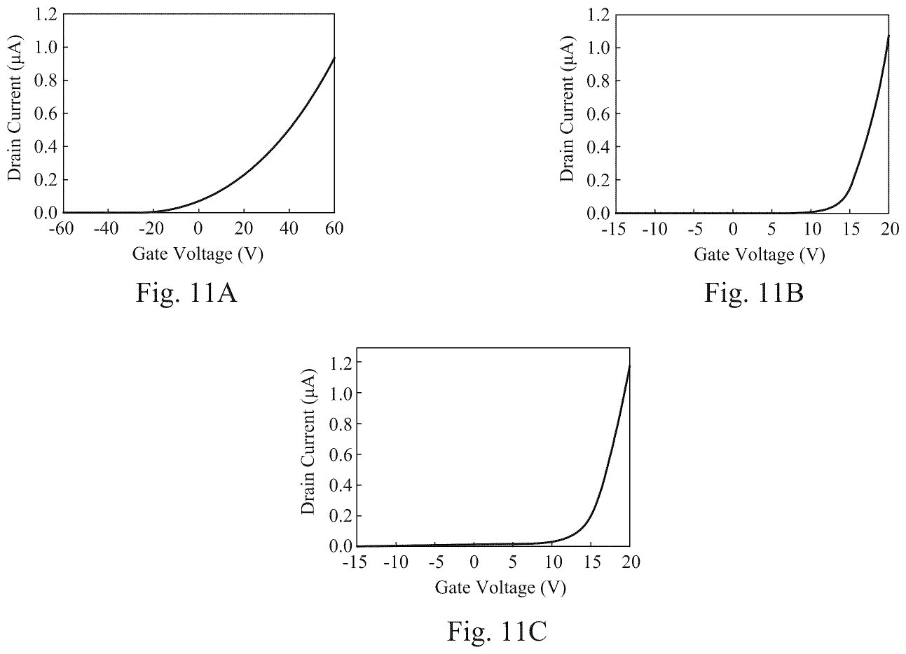

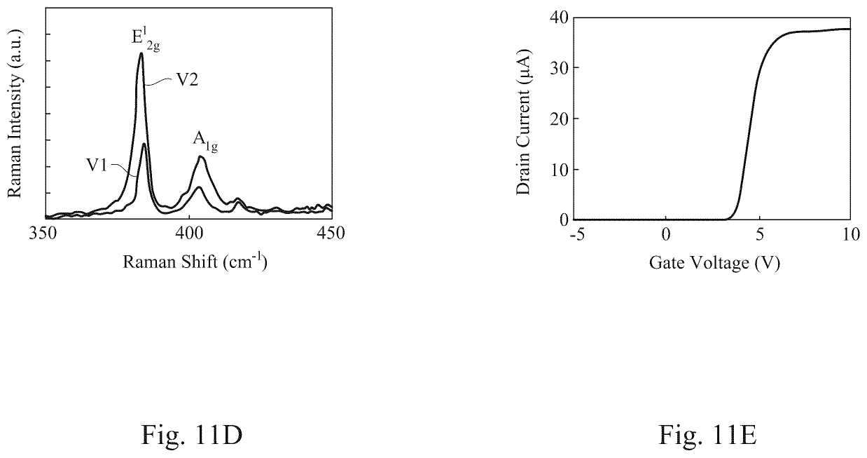

In some embodiments, the impact of device geometry, such as the gate-to-channel separation (i.e., air gap AR1), can be evaluated through transfer characteristics, as shown in FIG. 11A. Specifically, FIG. 11A may present the transfer curve of a semiconductor device configured with an effective channel length L1 of approximately 400 nm, a channel width W1 of approximately 500 nm, and the lateral width D2 of the air gap AR1 of approximately 500 nm, measured under a drain-source voltage (V_{DS}) of 1.0 V. The transfer curve can demonstrates that clear drain current modulation is achievable using the lateral in-plane gate electrodes, thereby confirming that the IPGT architecture is compatible with 2D materials such as MoS₂ for effective field-effect control. In some embodiments, relatively high gate voltages can be required to transition the device as shown FIG. 8D between its ON and OFF states, indicating reduced electrostatic coupling efficiency due to the wide air gap. Additionally, the device may exhibits a relatively low ON/OFF current ratio of approximately 10⁴. This may suggest that while the fundamental operation of the IPGT structure is validated, further optimization of the gate-to-channel spacing can be conducted to enhance switching performance, reduce operating voltages, and achieve higher current modulation ratios suitable for low-power and high-efficiency electronic applications.

In some embodiments, the performance enhancement achieved by reducing the gate-to-channel separation in the in-plane gate transistor (IPGT) architecture can be illustrated through the transfer characteristics shown in FIG. 11B. FIG. 11B can present the transfer curve of a semiconductor device configured with an effective channel length L1 of approximately 400 nm, a channel width W1 of approximately 500 nm, and a reduced lateral width D2 of air gap AR1 of approximately 250 nm, measured at a drain-source voltage (VDS) of 1.0 V. As illustrated in FIG. 11B, decreasing the air gap from 500 nm (as previously shown in FIG. 11A) to 250 nm can improve the electrostatic coupling between the in-plane gate electrodes (e.g., gate metal 130G) and the TMD channel (e.g., channel portion 110A of the TMD layer 110). Specifically, the device with a 250 nm gate-to-channel separation may require about 15-25 V of gate voltage to achieve a drain current level of approximately 0.5-1.5 μA, indicating more efficient gate control and reduced threshold voltage. Furthermore, the ON/OFF current ratio can be increased to 10⁷ to more effectively deplete carriers within the channel region and fully switch off the device.

In some embodiments, the field-effect mobility (μ) of the device associated with FIG. 11B can be quantitatively derived using the formula: μ=(dI_{DS}/IV_{GS})×(L1/W1)×(t/ε)×(1/V_{DS}), where the parameters include a channel width W1 of 500 nm, an effective channel length L1 of 400 nm, a dielectric constant (ε) of 1 corresponding to air, and an oxide thickness (t) of 250 nm, which in this configuration represents the physical separation between the gate metal 130G and the channel portion 110A of the TMD layer 110. Applying these values can yields a calculated field-effect mobility of approximately 67.9 cm²/(V×s). This enhanced mobility, when compared to the single-digit cm²/V·s values observed in monolayer TMD bottom-gate (BG) transistors, could be attributed to reduced scattering effects, improved carrier transport due to the absence of a gate dielectric, or optimized electrostatic control inherent to the lateral gate configuration. Therefore, FIG. 11B may show that scaling down the gate-to-channel separation not only improves switching characteristics but also promotes superior carrier mobility.

As illustrated in FIG. 8E, an effective channel length L2 can be defined along the X-direction, representing the distance over which charge carriers travel between the source and drain electrodes (i.e., source/drain metals 130SD) within the TMD layer 110. A channel width W2 can be defined along the Y-direction, representing the lateral extent of the conduction path available for carrier transport. To evaluate the impact of increased channel width on device performance, a device can be formed with the effective channel length L2 of approximately 400 nm, the channel width W2 of approximately 1000 nm, and the gate-to-channel separation (i.e., lateral width D3 of air gap AR2) of approximately 250 nm. The electrical characteristics of this device, measured at VDS=1.0 V, can be presented in FIG. 11C.

In some embodiments, the transfer curve shown in FIG. 11C may demonstrates that, despite the wider channel, drain current modulation under varying gate biases is still achievable, confirming that the lateral in-plane gate architecture remains functional. The device shown in FIG. 8E may exhibit an ON/OFF current ratio of approximately 1000, reflecting a controlled modulation of carriers near the gate regions, while maintaining a conductive path in the central portion of the 1000 nm-wide channel under a negative gate bias of approximately −10 to −20 V. This characteristic may result from the IPGT structure as shown in FIG. 8E, where the gate metals 130G are positioned coplanar with the TMD channel. In this configuration, the lateral electric field is concentrated near the channel edges, offering modulation in those regions while allowing the central portion of wider channels, such as channel W2 is about equal to 1000 nm, to maintain partial conductivity under negative bias conditions.

In some embodiments, under positive gate biases, the device as shown in FIG. 8E can demonstrate similar turn-on behavior and drain current levels to that of a device with a 500 nm-wide channel, as shown in FIG. 8D. This suggests that, regardless of the physical channel width W2, approximately 500 nm of the channel adjacent to the gate electrode (e.g., gate metal 130G) is effectively influenced by the lateral electric field. In some embodiments, a drain current, such as approximately 0.8-1.4 μA, can be recorded at a gate bias of approximately 15-25 V compared to the narrower device as shown in FIG. 8D, indicating that the additional unmodulated channel area contributes marginally to conduction but is not actively controlled by the gate. As a result, although the channel width is approximately 1000 nm, the device effectively may utilize around 500 nm for gate-controlled operation. This focused modulation may lead to a lower calculated field-effect mobility, with the wider channel device showing a mobility of approximately 30.6 cm²/V·s compared to approximately 67.9 cm²/V·s for the 500 nm-wide device. This behavior may show how the IPGT architecture maintains stable performance by limiting gate influence to the regions where it is most effective, offering consistent and reliable operation even as channel dimensions increase.

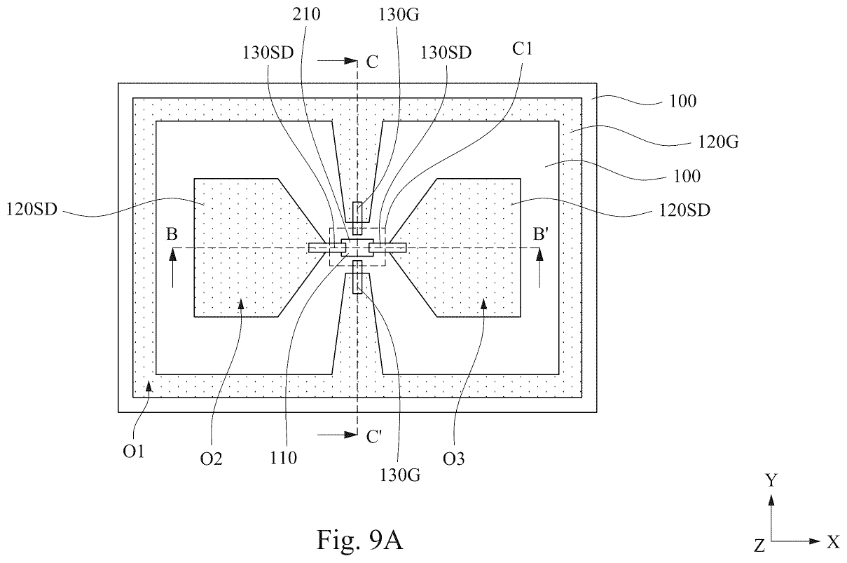

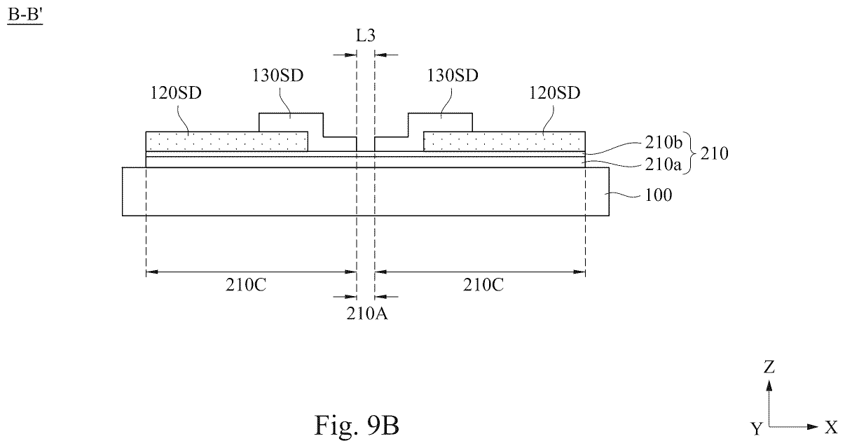

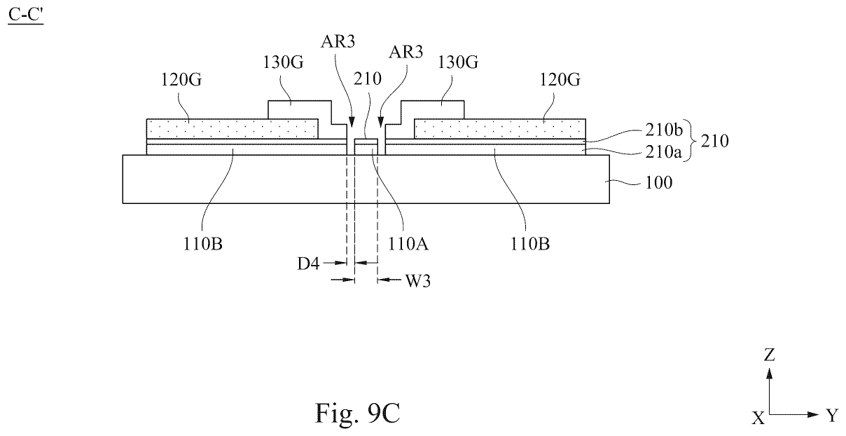

Reference is made to FIGS. 9A-9C. FIGS. 9A-9C illustrates schematic views of a semiconductor device 20 corresponding to the structure as shown in FIGS. 8A-8C in accordance with some embodiments of the present disclosure. While FIGS. 9A-9C illustrate embodiments of the semiconductor device 20 with a different structural configuration than the semiconductor device 20 in FIGS. 1A-8E, the present disclosure may repeat reference numerals and/or letters in the various examples. This repetition is for simplicity and clarity and does not dictate a relationship between the various embodiments and/or configurations discussed.

As shown in FIGS. 9A-9C, a distinction from the embodiments shown in FIGS. 1A-8E may lie in the configuration of the TMD layer 210, which includes a bi-layer transition metal dichalcogenide (TMD) structure formed by stacking two monolayers. In some embodiments, the TMD layer 210 can be formed through two sequential transferring processes, as described in FIGS. 1A-1F, utilizing a polydimethylsiloxane (PDMS)-based stamping method to transfer each monolayer onto the substrate 100. This process enables the controlled assembly of a high-quality bi-layer TMD structure, which serves as the active semiconductor layer in the IPGT device architecture illustrated in FIGS. 9A-9C, following the same fabrication flow outlined in FIGS. 2A-8C.

As shown in FIGS. 9A-9C, the TMD layer 210 can include a first layer 210a and a second layer 210b, where the second layer 210b is positioned directly above the first layer 210a and directly contacts the first layer 210a. In some embodiments, the first and second layers 210a and 210b can be monolayers of TMD materials, aligned to form a uniform bi-layer stack. The first layer 210a and second layer 210b may be made of the same material, such as MoS₂, to maintain consistent electronic properties across the channel region. Alternatively, in other embodiments, the first layer 210a and second layer 210b can be made of different TMD materials, enabling heterostructure engineering to tailor the band structure, carrier mobility, or other electronic characteristics of the device. In some embodiments, the lower first layer 210a can function as part of the active channel while also acting as a separation layer, effectively isolating the upper channel region (i.e., second layer 210b) from potential substrate-induced disturbances such as charge impurities or surface roughness, such that the lower first layer 210a can enhance carrier transport and overall device performance by mitigating adverse substrate interactions. In some embodiments, the first layer 210a can be in direct contact with the second layer 210b.

As depicted in the cross-sectional view of FIG. 9B, the channel portion 210A of the TMD layer can be exposed from the source/drain metals 130SD, which form electrical contacts enabling carrier injection into and out of the channel. In FIG. 9B, the etched TMD layer 210 can further includes source/drain regions 210C underlying the source/drain metals 130SD. In FIG. 9C, the remaining portion 210B of the TMD layer 210 can be shown directly underneath and in contact with the gate metals 130G, indicating that the gate electrode is structurally and electrically interfaced with the isolated TMD region.

In some embodiments, to ensure high-quality interface and surface cleanliness, the PDMS-stamping method can be employed for the transfer of both monolayers (e.g., first layer 210a and second layer 210b). Compared to poly(methyl methacrylate) (PMMA)-assisted transfer techniques, PDMS stamping may minimize residual contamination on the 2D material surfaces (e.g., first layer 210a and second layer 210b), which in turn preserves the intrinsic properties of the TMD layer 210, reducing defect densities, and improving contact quality.

As shown in FIGS. 9A-9C, the bi-layer TMD IPGT can be defined by structural parameters, including an effective channel length L3 (see FIG. 9B), a channel width W3 (see FIG. 9C), and a gate-to-channel separation (i.e., lateral width D4 of air gap AR3) (see FIG. 9C). In some embodiments, the material and electrical characteristics of this device configuration can be analyzed through Raman spectroscopy and transfer curve measurements. Specifically, FIG. 11D presents the Raman spectra for devices fabricated with single-layer and bi-layer TMD structures, each having an effective channel length of approximately 400 nm, a channel width of approximately 500 nm, and the lateral width D4 of the air gap AR3 of approximately 250 nm. Complementing this, FIG. 11E presents the corresponding transfer curve of the bi-layer TMD IPGT, measured at VDS =1.0 V, to evaluate its electrical performance. In some embodiments, Raman spectroscopy can be a non-destructive characterization technique used to probe the vibrational modes of materials. When monochromatic light interacts with a material, most photons scatter elastically, but a small fraction may undergoe inelastic scattering, known as the Raman effect. This may result in shifts in the energy of the scattered photons, which correspond to specific vibrational modes of the material's atomic lattice. In the context of 2D materials like transition metal dichalcogenides (TMDs), Raman spectra can provide critical insights into layer thickness, crystal quality, strain, doping levels, and interlayer coupling.

In FIG. 11D, the Raman spectra recorded after the transfer processes for the devices shown in FIGS. 8A-9C differentiate between a single-layer and a bi-layer TMD structure. The spectrum V1 corresponds to a semiconductor device incorporating a single layer of TMD (e.g., MoS₂) configuration, while the spectrum V2 corresponds to a semiconductor device incorporating a bi-layer TMD (e.g., MoS₂) configuration. Both spectra may exhibit the characteristic E¹_{2g} (in-plane vibrational mode) and A_{1g} (out-of-plane vibrational mode) peaks associated with TMD (e.g., MoS₂). An observation from the FIG. 11D can be the increase in the peak separation Δk between the E¹_{2g} and A₁g modes as the number of TMD (e.g., MoS₂) layers increases. For the single-layer device, Δk is approximately 19.3 cm⁻¹, whereas for the bi-layer device, Δk increases to approximately 21.0 cm⁻¹. This shift can be a well-established indicator of successful bi-layer formation, as interlayer interactions in TMDs lead to measurable changes in vibrational energy states. Thus, the Raman spectra in FIG. 11D may not only confirm the integrity and thickness of the transferred TMD layers but also demonstrate the precision of the fabrication process.

In FIG. 11E, the bi-layer TMD IPGT may demonstrates a drain current that is approximately 30 to 40 times higher than that of the monolayer TMD IPGT shown in FIGS. 8A-8C, which in turn increases in current indicates a higher electron density within the bi-layer TMD channel. The enhanced carrier concentration can be further supported by a lower threshold voltage, reflecting more efficient channel formation and easier carrier accumulation under gate bias. Additionally, the transfer characteristics may reveal a saturation region, a hallmark of well-controlled carrier transport and improved gate modulation in field-effect transistors. The performance of the bi-layer TMD IPGT, when compared to its monolayer counterpart, can facilitate greater electron accumulation under positive gate biases, enabling the device to reach higher current levels and achieve saturation more effectively. Additionally, the multi-layer TMD IPGT may contribute to enhanced electron storage capacity within the TMD film. Owing to this efficient gate control and optimized channel properties, the bi-layer TMD (e.g., MoS₂) IPGT may achieve a field-effect mobility of approximately 6365.9 cm²/V·s. Furthermore, the device may maintain a high ON/OFF current ratio exceeding approximately 10⁹, demonstrating improved switching behavior, low leakage, and suitability for low-power applications.

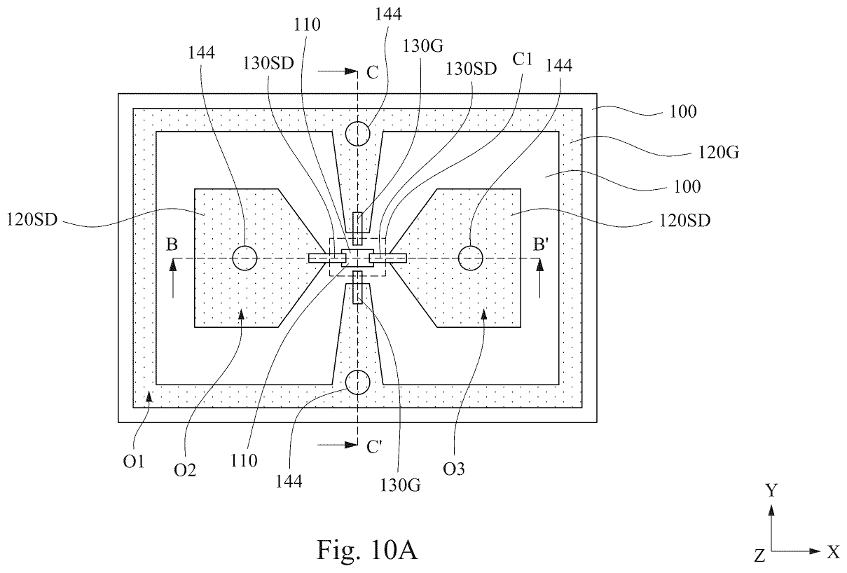

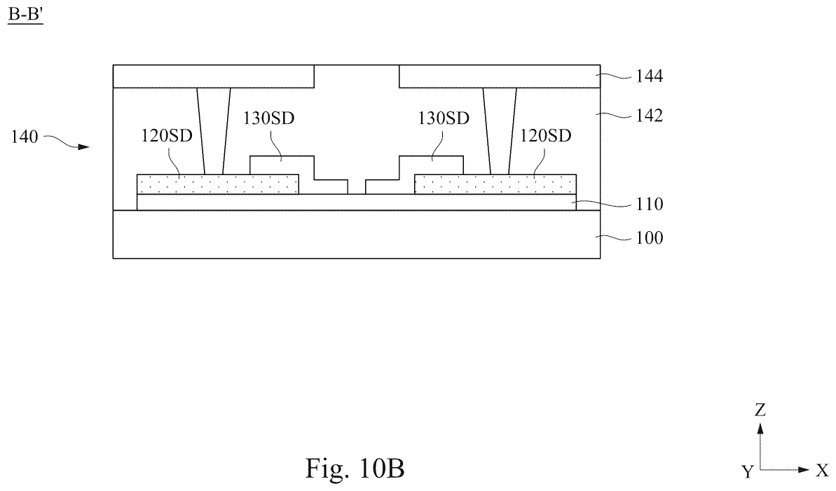

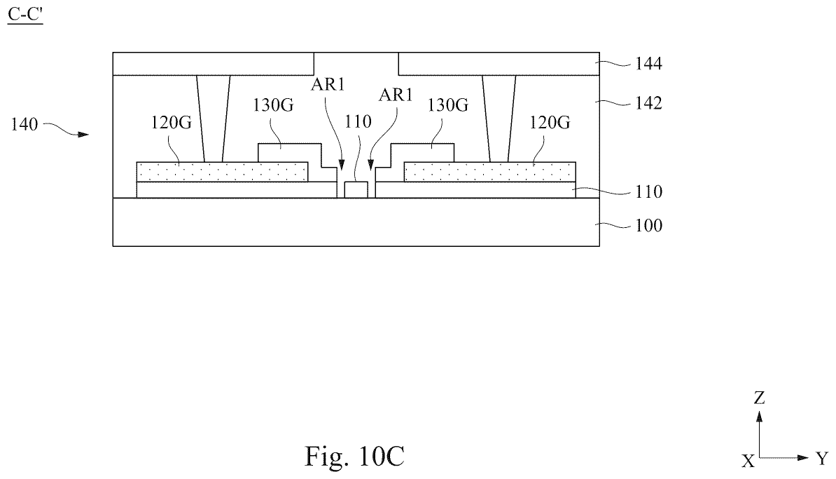

Reference is made to FIGS. 10A-10C. An interconnect structure 140 can be formed over the gate metals 130G and source/drain metals 130SD. The interconnect structure 140 can include dielectric layers 142 and layers of conductive features 144 in the dielectric layers 142. The dielectric layers 142 may include low-k dielectric layers formed of low-k dielectric materials. The dielectric layers 142 may further include passivation layers, which are formed of non-low-k and dense dielectric materials such as undoped silicate-glass (USG), silicon oxide, silicon nitride, or the like, or combinations thereof over the low-k dielectric materials. The dielectric layers 142 may also include polymer layers. The conductive features 144 may include conductive lines and vias, which may be formed using damascene processes. The conductive features 144 may include metal lines and metal vias, which include diffusion barriers and a copper containing material over the diffusion barriers. In some embodiments, the conductive features 144 can include gold (Au), titanium (Ti), palladium (Pd), platinum (Pt), nickel (Ni), aluminum (Al), copper (Cu), other suitable conductive materials, or combinations thereof. In some embodiments, metal stacks like Ti/Au, Cr/Au, or Pd/Au may be used. Other alternatives can include graphene, carbon nanotube-based electrodes, or transparent conductive oxides like indium tin oxide (ITO) and aluminum-doped zinc oxide (AZO). In some embodiments, conductive metal nitrides such as titanium nitride (TiN) can also be used for the mechanical robustness and chemical stability of the conductive features 144.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a TMD (e.g., MoS₂) in-plane gate transistor (IPGT). In some embodiments, the fabrication of TMD IPGT device can include transferring CVD-grown TMD onto a substrate using polydimethylsiloxane (PDMS) stamping to ensure consistent film attachment. Photolithography and metal lift-off can be used to form metal electrodes. The TMD IPGT device can have improved current modulation via in-plane gates.

In some embodiments, a semiconductor device includes a substrate, a first transition metal dichalcogenide (TMD) layer, a plurality of source/drain metals, and a gate metal. The first TMD layer disposed over the substrate. The first TMD layer includes a channel region and a plurality of source/drain regions on opposite sides of the channel region. The source/drain metals are disposed over the substrate and electrically coupled to the source/drain regions of the first TMD layer, respectively. The gate metal is disposed over the substrate and laterally spaced from the channel region of the first TMD layer. The gate metal is positioned such that the gate metal does not overlap the first TMD layer in a vertical direction.

In some embodiments, the first TMD layer comprises molybdenum disulfide, tungsten disulfide, tungsten diselenide, or combinations thereof. In some embodiments, the first TMD layer is a monolayer. In some embodiments, the semiconductor device further includes a separation layer between the first TMD layer and the substrate. In some embodiments, the separation layer comprises transition metal dichalcogenide. In some embodiments, the separation layer is a monolayer. In some embodiments, the substrate comprises sapphire. In some embodiments, the semiconductor device further includes a second TMD layer disposed between the gate metal and the substrate. The second TMD layer is laterally spaced from the first TMD layer and positioned at a same elevation as the first TMD layer. In some embodiments, the gate metal is positioned at an elevation higher than that of the first TMD layer. In some embodiments, the gate metal is laterally spaced from the channel region of the first TMD layer by a distance ranging from about 1-250 nm.

In some embodiments, a semiconductor device includes a substrate, a transition metal dichalcogenide (TMD) monolayer, a molybdenum disulfide monolayer, a plurality of source/drain metals, and a gate metal. The TMD monolayer is disposed over the substrate. The molybdenum disulfide monolayer is stacked on the TMD monolayer. The source/drain metals are disposed over and electrically coupled to the molybdenum disulfide monolayer. The gate metal is disposed over the substrate and laterally spaced from the TMD monolayer and the molybdenum disulfide monolayer. The gate metal does not overlap the TMD monolayer or the molybdenum disulfide monolayer in a vertical direction.

In some embodiments, the substrate comprises silicon oxide, hafnium oxide, aluminum oxide, or combinations thereof. In some embodiments, the TMD monolayer is in contact with the molybdenum disulfide monolayer. In some embodiments, the source/drain metals comprises copper, platinum, or a combination thereof. In some embodiments, a distance between the source/drain metals ranges from about 1-500 nm.

In some embodiments, a method includes transferring a first transition metal dichalcogenide (TMD) monolayer onto a substrate; forming a plurality of source/drain metal contacts over source/drain regions of the first TMD layer; forming a gate metal over the substrate, wherein the gate metal is laterally spaced from the first TMD layer and does not overlap the first TMD layer in a vertical direction, and wherein the gate metal and the source/drain metal contacts are positioned in a coplanar configuration relative to the a channel region of the TMD active layer.

In some embodiments, transferring the first TMD monolayer onto the substrate is performed using a stamping process. In some embodiments, the first TMD monolayer comprises molybdenum disulfide, tungsten disulfide, tungsten diselenide, or combinations thereof. In some embodiments, the method further includes transferring a second TMD monolayer onto the first TMD monolayer. In some embodiments, forming the gate metal is performed under a temperature lower than about 100 °C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first transition metal dichalcogenide (TMD) layer disposed over the substrate, the first TMD layer comprising a channel region and a plurality of source/drain regions on opposite sides of the channel region;
a plurality of source/drain metals disposed over the substrate and electrically coupled to the source/drain regions of the first TMD layer, respectively; and
a gate metal disposed over the substrate and laterally spaced from the channel region of the first TMD layer, wherein the gate metal is positioned such that the gate metal does not overlap the first TMD layer in a vertical direction.

2. The semiconductor device of claim 1, wherein the first TMD layer comprises molybdenum disulfide, tungsten disulfide, tungsten diselenide, or combinations thereof.

3. The semiconductor device of claim 1, wherein the first TMD layer is a monolayer.

4. The semiconductor device of claim 1, further comprising:
a separation layer between the first TMD layer and the substrate.

5. The semiconductor device of claim 4, wherein the separation layer comprises transition metal dichalcogenide.

6. The semiconductor device of claim 4, wherein the separation layer is a monolayer.

7. The semiconductor device of claim 1, wherein the substrate comprises sapphire.

8. The semiconductor device of claim 1, further comprising:
a second TMD layer disposed between the gate metal and the substrate, wherein the second TMD layer is laterally spaced from the first TMD layer and positioned at a same elevation as the first TMD layer.

9. The semiconductor device of claim 1, wherein the gate metal is positioned at an elevation higher than that of the first TMD layer.

10. The semiconductor device of claim 1, wherein the gate metal is laterally spaced from the channel region of the first TMD layer by a distance ranging from about 1-250 nm.

11. A semiconductor device, comprising:
a transition metal dichalcogenide (TMD) monolayer disposed over a substrate;
a molybdenum disulfide monolayer stacked on the TMD monolayer;
a plurality of source/drain metals disposed over and electrically coupled to the molybdenum disulfide monolayer; and
a gate metal disposed over the substrate and laterally spaced from the TMD monolayer and the molybdenum disulfide monolayer, wherein the gate metal does not overlap the TMD monolayer or the molybdenum disulfide monolayer in a vertical direction.

12. The semiconductor device of claim 11, wherein the substrate comprises silicon oxide, hafnium oxide, aluminum oxide, or combinations thereof.

13. The semiconductor device of claim 11, wherein the TMD monolayer is in contact with the molybdenum disulfide monolayer.

14. The semiconductor device of claim 11, wherein the source/drain metals comprises copper, platinum, or a combination thereof.

15. The semiconductor device of claim 11, wherein a distance between the source/drain metals ranges from about 1-500 nm.

16. A method, comprising:
transferring a first transition metal dichalcogenide (TMD) monolayer onto a substrate;
forming a plurality of source/drain metal contacts over source/drain regions of the first TMD layer; and
forming a gate metal over the substrate, wherein the gate metal is laterally spaced from the first TMD layer and does not overlap the first TMD layer in a vertical direction, and wherein the gate metal and the source/drain metal contacts are positioned in a coplanar configuration relative to the a channel region of the TMD active layer.

17. The method of claim 16, wherein transferring the first TMD monolayer onto the substrate is performed using a stamping process.

18. The method of claim 16, wherein the first TMD monolayer comprises molybdenum disulfide, tungsten disulfide, tungsten diselenide, or combinations thereof.

19. The method of claim 16, further comprising:
transferring a second TMD monolayer onto the first TMD monolayer.

20. The method of claim 16, wherein forming the gate metal is performed under a temperature lower than about 100 °C.
